(19) United States
(12) Patent Application Publication
(10) Pub. No.: US 2012/0202311 A1
(43) Pub. Date: Aug. 9, 2012

(54) METHOD OF MANUFACTURING IMAGE SENSOR

(75) Inventors: Wen-Chen CHIANG, Hsinchu City (TW); Ko-Ting Chen, Zhongliao Township (TW)

(73) Assignee: UNITED MICROELECTRONICS CORP., Hsinchu (TW)

(21) Appl. No.: 13/024,037

(22) Filed: Feb. 9, 2011

(51) Int. Cl. H01L 31/18

(52) U.S. Cl. 438/70; 257/E31.085

(57) ABSTRACT

A method of manufacturing image sensor includes the following steps. A substrate having a first region and a second region is provided. A plurality of image sensing components and a periphery circuit are formed on the substrate in the first region and the second region respectively. A first conductive layer and a first dielectric layer are formed on the substrate. An etch stop layer is formed on the first dielectric layer. A second conductive layer is formed on the etch stop layer in the second region. A second dielectric layer is formed on the substrate. The second dielectric layer on the etch stop layer in the first region is etched to be removed. The etch stop layer in the first region is removed to form a space. A color filter array is disposed in the space.

### FIELD OF THE INVENTION

The present invention relates to a method of manufacturing an image sensor, and particularly to a method of manufacturing a complementary metal oxide semiconductor (CMOS) image sensor.

### BACKGROUND OF THE INVENTION

FIG. 1 illustrates a schematic, top view of a CMOS image sensor (CIS) chip. Referring to FIG. 1, a CIS chip 1 includes a sensor region 11 and a periphery region 12. The sensor region 11 is used for receiving outside optical signals to form analog image signals in an electrical power manner. The periphery region 12 is used for disposing a circuit and transforming the analog image signals into digital image signals to output.

A portion of the dielectric layer in the sensor region is generally removed to reduce the effect of the dielectric layer to the light intensity. Further, due to the removal of the portion of the dielectric layer in the sensor region, a distance from the photodiode to the micro-lenses and the color filter array is also shortened, thereby reducing the length of the light path. However, during removing the portion of the dielectric layer in the sensor region to form a space for receiving the color filter array, the portion of the dielectric layer in the sensor region can not be removed entirely by using a conventional removing method. Thus, a remaining dielectric material of the portion of the dielectric layer in the sensor region will affect a cross-sectional configuration of the space for receiving the color filter array, thereby affecting the quality of the CIS chip and increasing the risk of damaged products with the CIS chip.

Therefore, what is needed is to a method of manufacturing an image sensor to overcome the above disadvantages.

### SUMMARY OF THE INVENTION

The present invention provides a method of manufacturing image sensor including the following steps. A substrate is provided. The substrate has a first region and a second region. A plurality of image sensing components are formed on the substrate in the first region. A periphery circuit is formed on the substrate in the second region. A first conductive layer and a first dielectric layer are formed on the substrate. An etch stop layer is formed on the first dielectric layer. A second conductive layer is formed on the etch stop layer in the second region. A second dielectric layer is formed on the substrate to cover the second conductive layer and the etch stop layer. The second dielectric layer on the etch stop layer in the first region is etched to be removed. The etch stop layer in the first region is removed to form a space. A color filter array is disposed in the space.

In one embodiment of the present invention, the substrate is a silicon substrate, and each of the image sensing components is a complementary metal oxide semiconductor image sensor.

In one embodiment of the present invention, the etch stop layer is either a silicon oxynitride layer or a silicon nitride layer, and either the silicon oxynitride layer or the silicon nitride layer is formed by a plasma-enhanced chemical vapor deposition method.

In one embodiment of the present invention, the second dielectric layer is formed by depositing a silicon oxide layer.

In one embodiment of the present invention, the planarization process applied to the second dielectric layer comprises a chemical mechanical polishing process applied to the second dielectric layer.

In one embodiment of the present invention, the method further includes a planarization process applied to the second dielectric layer, and the planarization process includes an etch back process applied to the second dielectric layer after the chemical mechanical polishing process.

In one embodiment of the present invention, the second conductive layer is only formed on the etch stop layer in the second region, and the second conductive layer is not formed on the etch stop layer in the first region.

In one embodiment of the present invention, the method further includes a step of removing a portion of the first dielectric layer in the first region after removing the etch stop layer to form the space.

In one embodiment of the present invention, the method further includes a step of forming a plurality of micro-lenses on the color filter array.

In one embodiment of the present invention, the method further includes a step of forming a dummy metal layer on the etch stop layer in the first region during forming the second conductive layer on the etch stop layer in the second region.

In one embodiment of the present invention, after etching to remove the second dielectric layer in the first region, the method further includes a step of removing the dummy metal layer.

In one embodiment of the present invention, before forming the first conductive layer on the substrate, the method further includes a step of forming at least a dielectric layer and at least a conductive layer on the substrate so that the at least a dielectric layer and the at least a conductive layer are located between the substrate and the first conductive layer.

The present invention also provides a method of manufacturing image sensor including the following steps. A substrate is provided. The substrate has a first region and a second region. A plurality of image sensing components are formed on the substrate in the first region. A periphery circuit is formed on the substrate in the second region. A first conductive layer, a first dielectric layer and an etch stop layer are formed on the substrate. The etch stop layer is in the first dielectric layer. A second conductive layer is formed on the first dielectric layer in the second region. A second dielectric layer is formed on the substrate to cover the second conductive layer and the first dielectric layer. The second dielectric layer and a portion of the first dielectric layer on the etch stop layer in the first region is etched to be removed. The etch stop layer in the first region is removed to form a space. A color filter array is disposed in the space.

In one embodiment of the present invention, the method further includes a step of forming a dummy metal layer on the first dielectric layer in the first region during forming the second conductive layer on the first dielectric layer in the second region.

In one embodiment of the present invention, after etching to remove the second dielectric layer and the portion of the first dielectric layer on the etch stop layer in the first region, the method further includes a step of removing the dummy metal layer.

The image sensor manufactured using the above method has good quality and can reduce the risk of damaged products with the image sensor.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 illustrates a schematic, top view of a CMOS image sensor chip.

FIGS. 2A-2H illustrate a process flow of a method of manufacturing an image sensor in accordance with an embodiment of the present invention.

FIGS. 3A-3D illustrate a process flow of a method of manufacturing an image sensor in accordance with another embodiment of the present invention.

FIG. 4 illustrates a partial process flow of a method of manufacturing an image sensor in accordance with still another embodiment of the present invention.

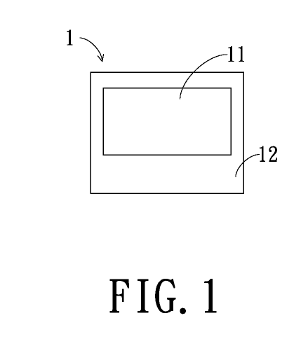

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

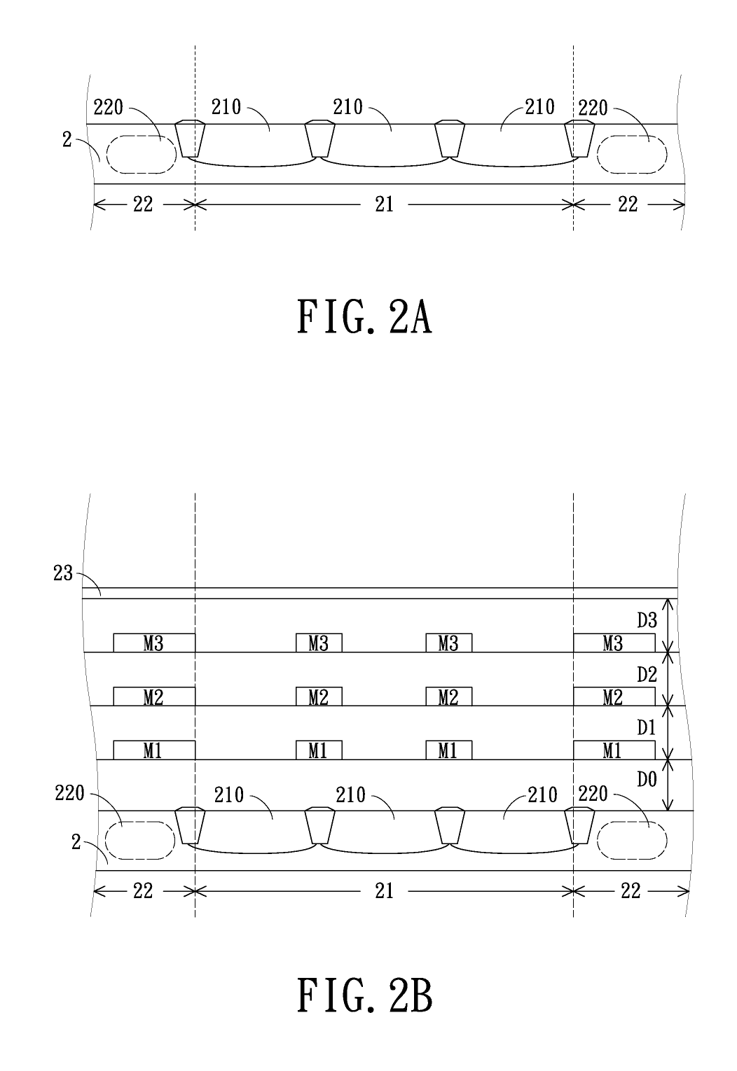

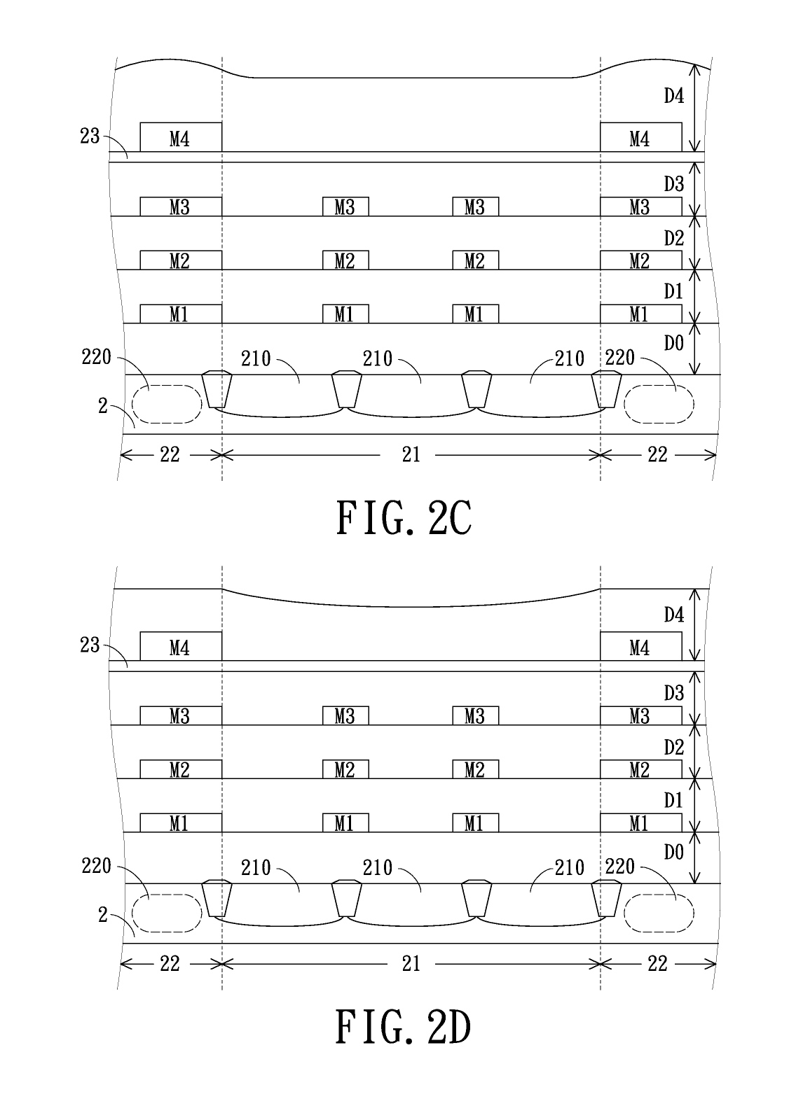

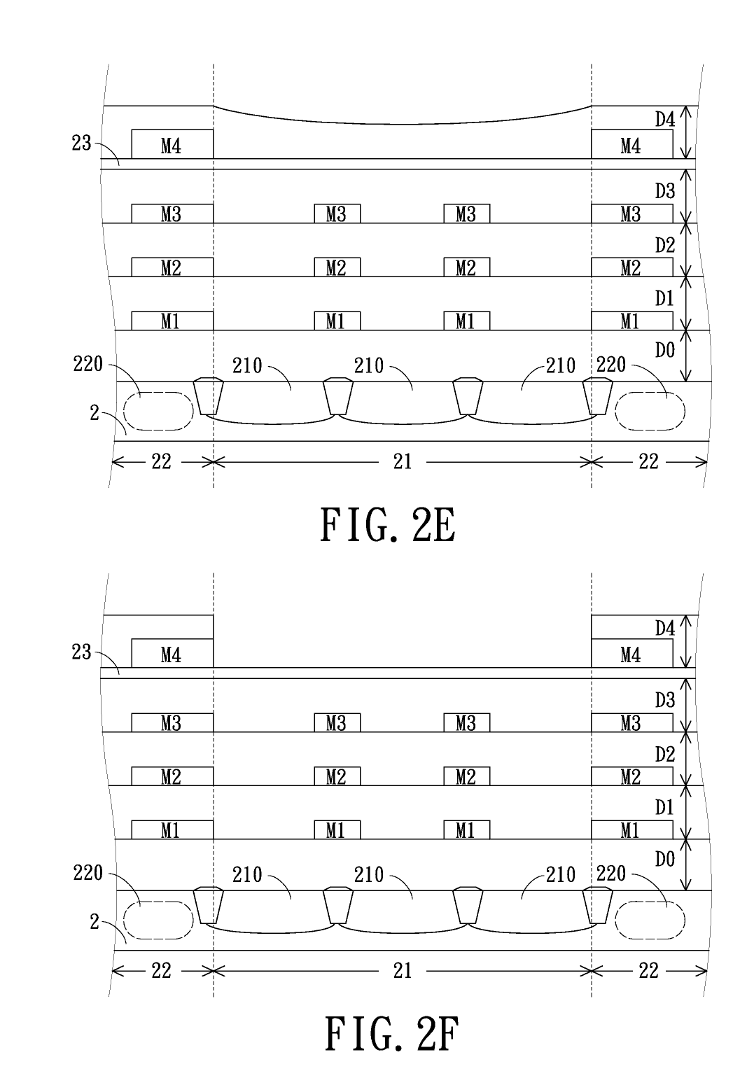

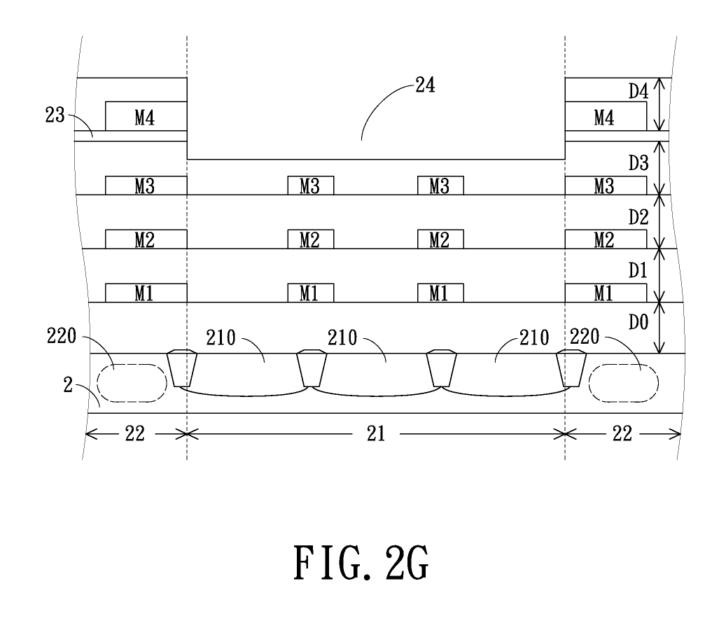

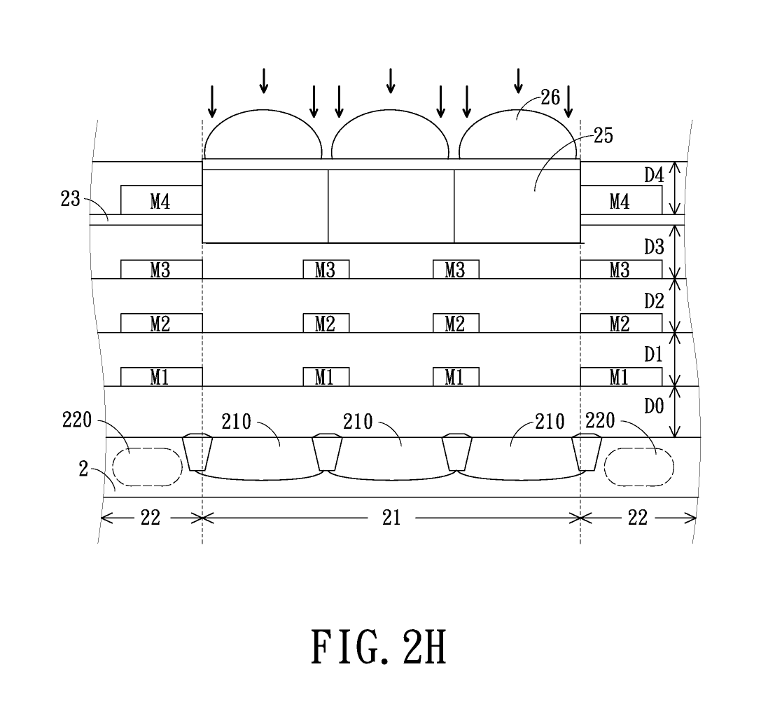

FIGS. 2A-2H illustrate a process flow of a method of manufacturing an image sensor in accordance with an embodiment of the present invention. At first, referring to FIG. 2A, a substrate 2, for example, a silicon substrate, is provided. The substrate 2 has a first region 21 and a second region 22 surrounding the first region 21. The first region 21 is configured for disposing a plurality of image sensing components 210 thereon, and the second region 22 is configured for disposing a periphery circuit 220 electrically connecting to the image sensing components 210 thereon. The image sensing component 210 can be, for example, photodiodes. The image sensing component 210 is configured for receiving outside optical signals to form analog image signals in an electrical power manner. The periphery circuit 220 is configured for transforming the analog image signals into digital image signals to output.

Referring to FIG. 2B, a routing structure including a plurality of conductive layers and a plurality of dielectric layers are formed on the substrate 2. In the present embodiment, the routing structure including four conductive layers and a plurality of dielectric layers. It is noted that the number of the conductive layers is not limited by the present embodiment, and the number of the conductive layers can be increase or decrease according to the demand. In the present embodiment, a dielectric layer D0, a conductive layer M1, a dielectric layer D1, a conductive layer M2, a dielectric layer D2, a conductive layer M3, a dielectric layer D3 are formed in sequence. The uppermost conductive layer (the conductive layer M3) is a first conductive layer, and the uppermost dielectric layer (the dielectric layer D3) is a first dielectric layer on the first conductive layer. Then, an etch stop layer 23 is formed on the first dielectric layer D3. The etch stop layer 23 can be, for example, a silicon oxynitride (SiON) layer or a silicon nitride (SiN) layer, which can be formed by a plasma-enhanced chemical vapor deposition (PECVD) method. A material of the dielectric layers D0, D1, D2, and D3 can be silicon oxide. A contact hole (not shown) is formed by removing a portion of the etch stop layer 23 and a portion of the dielectric layer D3 in the first region 21. In order to form the contact hole, two different etchants are provided to etch the dielectric layer D3 and the etch stop layer 23 in the first region 21 respectively, because the etch stop layer 23 and the dielectric layer D3 has a high etching aspect ratio. It is necessary for the dielectric layer D3 to have a surface with an adequate flatness. Thus, the etch stop layer 23 formed on the surface of the dielectric layer D3 can also have an adequate flatness.

Referring to FIG. 2C, a second conductive layer (i.e., a conducive layer M4) is formed on the etch stop layer 23 in the second region 22 using the photolithography process, and a second dielectric layer (i.e., a dielectric layer D4) is formed on the substrate 2 to cover the conductive layer M4 and the etch stop layer 23. In other words, the conductive layer M4 is only formed on the etch stop layer 23 in the second region 22, and the conductive layer M4 is not formed on the etch stop layer 23 in the first region 21. The dielectric layer D4 is a passivation layer and is configured for protecting the image sensor. The dielectric layer D4 can be formed by subsequently depositing high density plasma un-doped silicate glass (HDP-USG) and depositing tetraethoxy silane (TEOS) using a PECVD method. A thickness of the high density plasma un-doped silicate glass layer and a thickness of the tetraethoxy silane layer are respectively about 6000 angstroms and 10000 angstroms.

Next, a planarization process is applied to the dielectric layer D4. For example, referring to FIG. 2D, at first, a chemical mechanical polishing (CMP) process is applied to the dielectric layer D4. And then, referring to FIG. 2E, an etch back process is applied to the polished dielectric layer D4 to further thin the dielectric layer D4. As shown in FIG. 2D, after the CMP process, the dielectric layer D4 will be dishing in the first region 21 without the conductive layer M4 due to different polishing patterned density. In generally, the first region 21 with low polishing patterned density is over polished to make the dielectric layer D4 be dishing.

However, in the present embodiment of the invention, the etch stop layer 23 is disposed on the dielectric layer D3. Thus, when the dielectric layer D4 on the etch stop layer 23 in the first region 21 is etched to be removed to form a space as shown in FIG. 2F, the etch stop layer 23 can prevent the dielectric layer D3 from being etched. Thus, an etching time of the dielectric layer D4 can be increased so as to entirely remove the dielectric layer D4 on the etch stop layer 23 in the first region 21 to form the space with a good cross-sectional configuration as shown in FIG. 2F.

Next, referring to FIG. 2G, the etch stop layer 23 in the first region 21 is etched by another etchant to be removed to form a space 24. The spacer 24 is configured for receiving a color filter array. Further, a portion of the dielectric layer D3 in the first region 21 can be removed so that the color filter array in the space 24 can be closer to the image sensing components 210.

Next, referring to FIG. 2H, a color filter array 25 is formed in the receiving space 24, and a plurality of micro-lenses 26 are formed on the color filter array 25. The image sensor manufactured using the above method has good quality and can reduce the risk of damaged products with the image sensor.

However, when the pixels of the image sensing components 210 increase, an area of the first region 21 of the substrate 2 increases correspondingly. After the CMP process, the dielectric layer D4 will be dishing badly, only the etch stop layer 23 can not satisfy the demand of manufacturing the image sensor with good quality. Thus, another embodiment is described to solve the above problem.

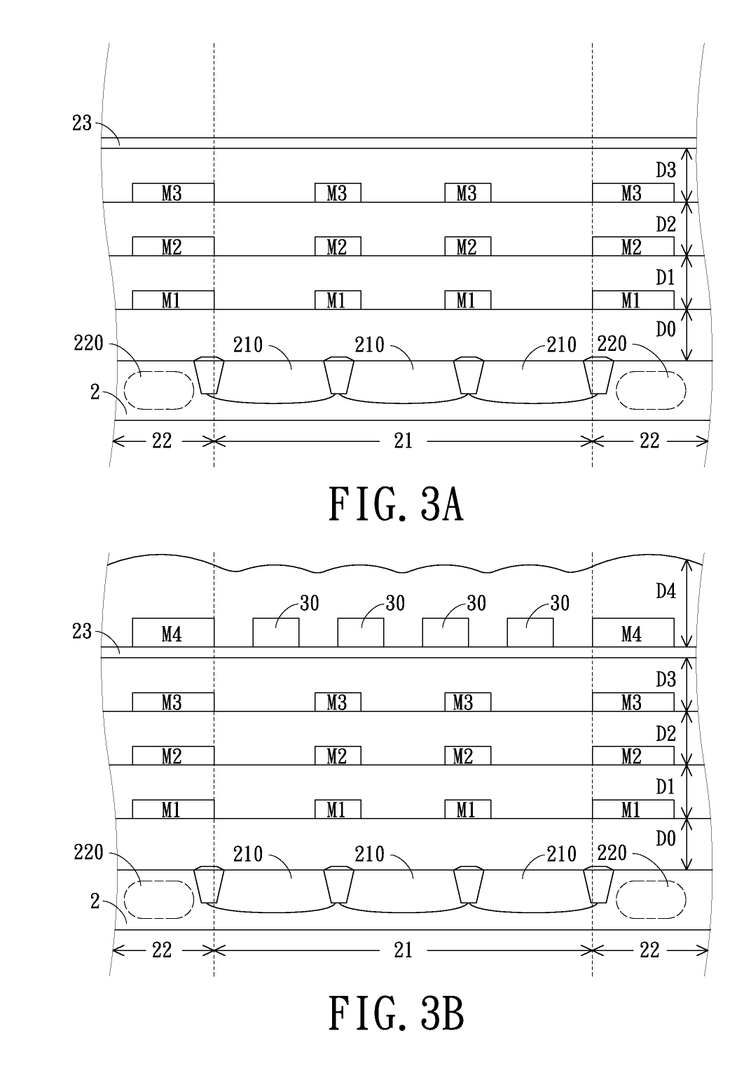

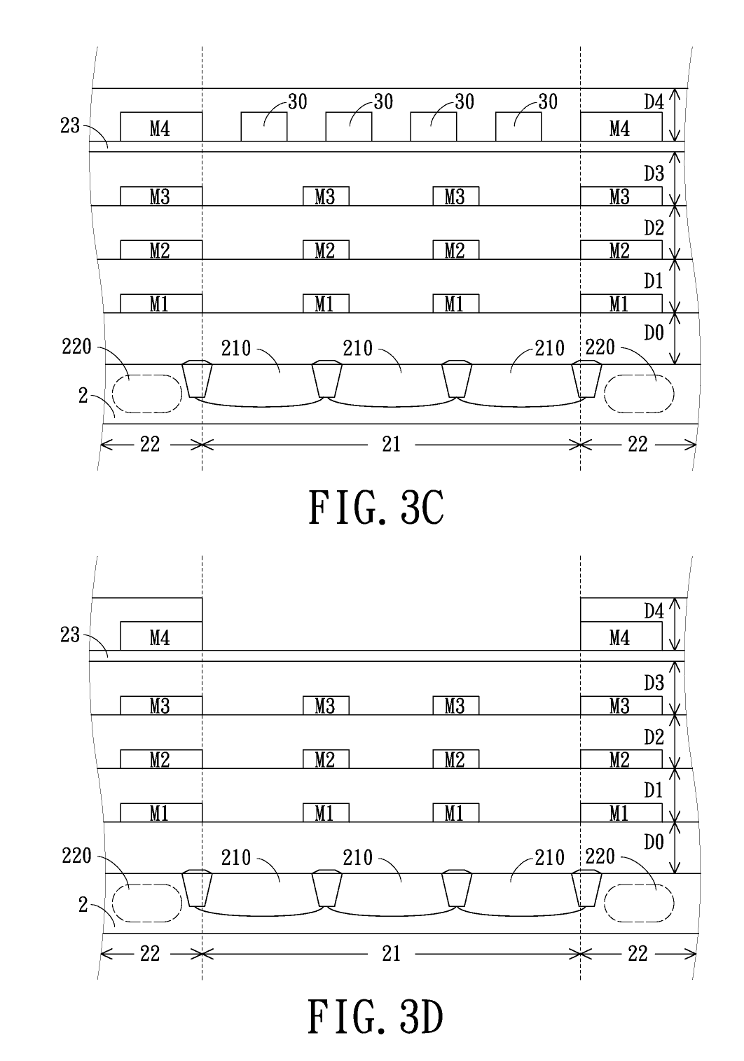

FIGS. 3A-3D illustrate a process flow of a method of manufacturing an image sensor in accordance with another embodiment of the present invention. FIG. 3A illustrates a structure similar to the structure shown in FIG. 2B. Referring to FIG. 3A, the etch stop layer 23 is formed on the dielectric layer D3.

Referring to FIG. 3B, during forming the conductive layer M4 using the photolithography process, a dummy metal layer 30 is also formed on the etch stop layer 23 in the first region 21. Then, the dielectric layer D4 is formed to cover the dummy metal layer 30, the conductive layer M4 and the etch stop layer 23. The dummy metal layer 30 is not a circuit and has not a circuit function. In other words, the dummy metal layer 30 is configured for increasing a polishing patterned intensity of the first region 21 so that the first region 21 and the second region 22 can have a similar polishing patterned intensity.

Therefore, referring to FIG. 3C, when the planarization process is applied to the dielectric layer D4, the dielectric layer D4 will not be dishing in the first region 21. The planarization process can include, for example, a CMP process and an etch back process. It is noted that, the etch back process can be omitted because the dielectric layer D4 is not dishing in the first region 21 after the CMP process.

Next, referring to FIG. 3D, at first, the dielectric layer D4 on the etch stop layer 23 in the first region 21 is etched to be removed to form the space. The etch stop layer 23 can prevent the dielectric layer D3 from being etched. Thus, an etching time of the dielectric layer D4 can be increased so as to entirely remove the dielectric layer D4 on the etch stop layer 23 in the first region 21. Then, the dummy metal layer 30 is removed to form the space with a good cross-sectional configuration as shown in FIG. 3D. The subsequent steps are similar to the steps as shown in FIGS. 2G and 2H, and are not described here.

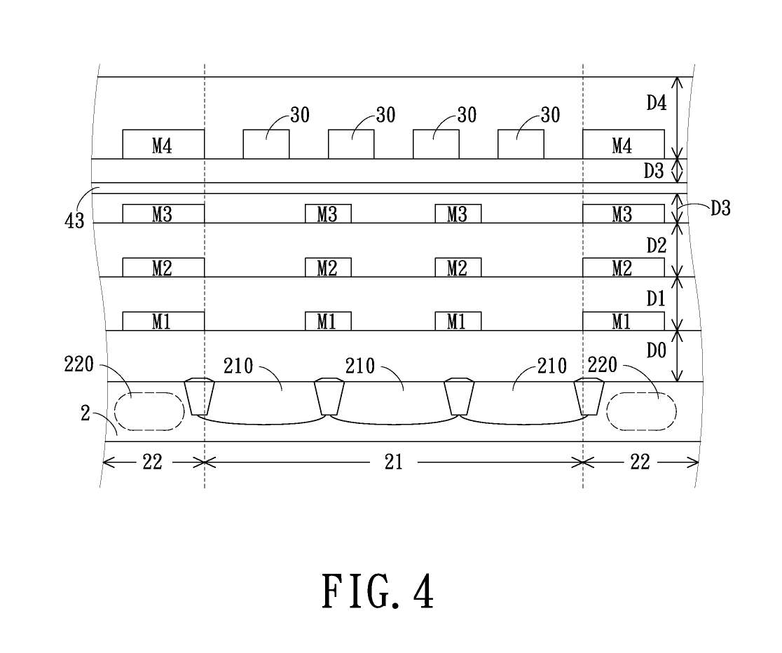

Additionally, FIG. 4 illustrates a partial process flow of a method of manufacturing an image sensor in accordance with still another embodiment of the present invention. In the present embodiment, the steps of manufacturing the image sensor is similar to the steps of the above two embodiments except that an etch stop layer 43 is formed in the first dielectric layer (i.e., the dielectric layer D3), as shown in FIG. 4. Thus, the etch stop layer 43 is sandwiched between the upper layer of the dielectric layer D3 and the lower layer of the dielectric layer D3. When forming the receiving space 24 for receiving the color filter array, the second dielectric layer (i.e., the dielectric layer D4) and a portion of the first dielectric layer (i.e., the upper layer of the dielectric layer D3) on etch stop layer 43 in the first region 21 can be etched to be removed successively. The etch stop layer 43 can prevent a portion of the first dielectric layer (i.e., the lower layer of the dielectric layer D3) from being etched. Then, the etch stop layer 43 in the first region 21 is removed to form the receiving space 24. It is noted that, the conductive layer M4 and the dummy metal layer 30 are respectively formed on the first dielectric layer D3 in the second region 22 and in the first region 21.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A method of manufacturing image sensor, comprising:
providing a substrate, the substrate having a first region and a second region;
forming a plurality of image sensing components on the substrate in the first region;
forming a periphery circuit on the substrate in the second region;
forming a first conductive layer on the substrate in the first region and the second region and forming a first dielectric layer on the substrate to cover the first conductive layer and directly contacted with the first conductive layer;
forming an etch stop layer on the first dielectric layer and directly contacted with the first dielectric layer;
forming a second conductive layer on the etch stop layer in the second region;
forming a second dielectric layer on the substrate to cover the second conductive layer and the etch stop layer;
etching the second dielectric layer to remove the second dielectric layer on the etch stop layer in the first region;
entirely removing the etch stop layer in the first region to form a space; and
disposing a color filter array in the space.

2. The method of manufacturing image sensor as claimed in claim 1, wherein the substrate is a silicon substrate, and each of the image sensing components is a complementary metal oxide semiconductor image sensor.

3. The method of manufacturing image sensor as claimed in claim 1, wherein the etch stop layer is either a silicon oxynitride layer or a silicon nitride layer, and either the silicon oxynitride layer or the silicon nitride layer is formed by a plasma-enhanced chemical vapor deposition method.

4. The method of manufacturing image sensor as claimed in claim 1, wherein the second dielectric layer is formed by depositing a silicon oxide layer.

5. The method of manufacturing image sensor as claimed in claim 1, further comprising applying a planarization process to the second dielectric layer, the planarization process comprises a chemical mechanical polishing process applied to the second dielectric layer.

6. The method of manufacturing image sensor as claimed in claim 5, wherein the planarization process applied to the second dielectric layer comprises an etch back process applied to the second dielectric layer after the chemical mechanical polishing process.

7. The method of manufacturing image sensor as claimed in claim 1, wherein the second conductive layer is only formed on the etch stop layer in the second region, and the second conductive layer is not formed on the etch stop layer in the first region.

8. The method of manufacturing image sensor as claimed in claim 1, further comprising removing a portion of the first dielectric layer in the first region after removing the etch stop layer to form the space.

9. The method of manufacturing image sensor as claimed in claim 1, further comprising forming a plurality of micro-lenses on the color filter array.

10. The method of manufacturing image sensor as claimed in claim 1, during forming the second conductive layer on the etch stop layer in the second region, further comprising forming a dummy metal layer on the etch stop layer in the first region.

11. The method of manufacturing image sensor as claimed in claim 10, after etching to remove the second dielectric layer in the first region, further comprising removing the dummy metal layer.

12. The method of manufacturing image sensor as claimed in claim 1, before forming the first conductive layer on the substrate, further comprising forming at least a dielectric layer and at least a conductive layer on the substrate so that the at least a dielectric layer and the at least a conductive layer are located between the substrate and the first conductive layer.

13. A method of manufacturing image sensor, comprising:
providing a substrate, the substrate having a first region and a second region;
forming a plurality of image sensing components on the substrate in the first region;
forming a periphery circuit on the substrate in the second region;
forming a first conductive layer on the substrate in the first region and the second region, forming a first dielectric layer and an etch stop layer on the substrate, the first conductive layer being covered by the first dielectric layer and directly contacted with the first dielectric layer, the etch stop layer being in the first dielectric layer and above the first conductive layer;
forming a second conductive layer on the first dielectric layer in the second region;
forming a second dielectric layer on the substrate to cover the second conductive layer and the first dielectric layer;
etching the second dielectric layer to remove the second dielectric layer in the first region and a portion of the first dielectric layer on the etch stop layer in the first region;
entirely removing the etch stop layer in the first region to form a space; and
disposing a color filter array in the space.

14. The method of manufacturing image sensor as claimed in claim 13, wherein the etch stop layer is either a silicon oxynitride layer or a silicon nitride layer, and either the silicon oxynitride layer or the silicon nitride layer is formed by a plasma-enhanced chemical vapor deposition method.

15. The method of manufacturing image sensor as claimed in claim 13, further comprising applying a planarization process to the second dielectric layer.

16. The method of manufacturing image sensor as claimed in claim 15, wherein the planarization process applied to the second dielectric layer comprises a chemical mechanical polishing process applied to the second dielectric layer.

17. The method of manufacturing image sensor as claimed in claim 13, wherein further comprising forming a plurality of micro-lenses on the color filter array.

18. The method of manufacturing image sensor as claimed in claim 13, during forming the second conductive layer on first dielectric layer in the second region, further comprising forming a dummy metal layer on the first dielectric layer in the first region.

19. The method of manufacturing image sensor as claimed in claim 18, after etching to remove the second dielectric layer in the first region and the portion of the first dielectric layer on the etch stop layer in the first region, further comprising removing the dummy metal layer.

20. The method of manufacturing image sensor as claimed in claim 13, before forming the first conductive layer on the substrate, further comprising forming at least a dielectric layer and at least a conductive layer on the substrate so that the at least a dielectric layer and the at least a conductive layer are located between the substrate and the first conductive layer.

21. The method of manufacturing image sensor as claimed in claim 13, wherein the second conductive layer is only formed on the etch stop layer in the second region, and the second conductive layer is not formed on the etch stop layer in the first region.
